(19) United States
(12) Patent Application Publication
(10) Pub. No.: US 2004/0203538 A1
(43) Pub. Date: Oct. 14, 2004

(54) Method and apparatus for transmission polarization selection for a cellular base station

(76) Inventors: Kari J. Leppanen, Helsinki (FI); Juha K. Laurila, Espoo (FI); Klaus Hugl, Helsinki (FI)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/224,324

(22) Filed: Aug. 21, 2002

(51) Int. Cl. H04B 1/02; H03C 7/02; H04B 7/02; H03C 1/62; H04B 17/00

(52) U.S. Cl. 455/101; 455/115.1

(57) ABSTRACT

A method and apparatus for transmission polarization selection that includes receiving a signal from a device where the signal is received at two or three polarizations each polarization being orthogonal to each other. The polarization receiving the signal having the best performance characteristics is determined. Transmissions to the device are routed through appropriate transceivers and antennas such that they are transmitted using a polarization the same as that receiving the signal having the best performance characteristics. Performance characteristics measured may include highest power level, highest signal to noise ratio (SNR), highest carrier to interference ratio (CIR), highest signal to noise plus interference ratio (SNIR), lowest bit error ratio (BER), or lowest block error ratio (BLER).

### BACKGROUND

1. Field of the Invention

This invention relates to cellular systems, and more specifically to transmission polarization selection for a cellular base station.

2. Discussion of the Related Art

Cellular mobile stations are used around the world. In a typical cellular system, a cellular base station transmits and receives information to/from one or more cellular mobile stations. Generally, the signal from a base station to a mobile station is transmitted on a single polarization. The polarization of the linearly polarized electromagnetic wave carrying the signal tells which way the plane of the electric field (polarization plane) is oriented.

If a base station uses polarization transmit diversity to transmit to a mobile station, two (or three) signals are transmitted on mutually orthogonal polarizations. Orthogonal relates to the fact that the angle between the polarization planes is 90°. For example, a signal may be transmitted using vertical polarization, and a second signal transmitted using horizontal polarization where the angle between the polarization planes is 90°. Moreover, two signals may be transmitted on orthogonal polarizations that are slanted, e.g., ±45°, with respect to the ground vertical. In this example, the signal may be transmitted with a polarization at −45°, and a second signal transmitted at an orthogonal polarization of +45°.

Matching the polarization used to transmit the signal with the polarization characteristics of the propagation channel between the base station and mobile station allows an increase in network capacity by way of reducing the transmission power required to serve a given mobile station. It has been shown that transmission polarization matching can be based on polarization measurement performed in reception, i.e. that on average there is a strong correlation between the channel polarization states of forward and reverse links.

In some current systems, the base station measures the direction of the polarization ellipse of an incoming uplink signal from a mobile station and adjusts the transmitted linear polarization of a signal transmitted to the mobile station to have the same polarization plane direction as that measured on the incoming signal. The uplink measurement is made using two (or three) receive antennas having orthogonal polarizations and comparing the amplitudes and phases of the respective signals in the base station receiver. This requires two (or three) reception chains at the base station. Similarly, any linear transmit polarization may be generated by using two (or three) orthogonally polarized transmission antennas (and corresponding transmitter chains) and by adjusting the relative amplitudes and phases of the two (or three) just transmitted signals correspondingly.

However, systems implementing this form of polarization matching require calibration systems at the base station and possibly a phasing circuit to turn polarization to any angle. A calibration system is required both in the reception and transmit chains of the base station. Otherwise, the relative phases and amplitudes of the signals on orthogonal polarizations cannot be measured or controlled. Moreover, these techniques require analog transmission chains for each used orthogonal polarization to be used simultaneously for each mobile station. This takes up hardware resources at the base station and therefore lowers its maximum traffic capacity.

Therefore, methods and apparatus for transmission polarization selection for a cellular base station are needed that increase network capacity without the requirement of a calibration system or the requirement of having analog transmit chains reserved for each used polarization and each simultaneously supported mobile station.

### SUMMARY OF THE INVENTION

The present invention relates to a method and apparatus for transmission polarization selection that includes receiving a signal from a device where the signal is received at two or three polarizations, each polarization being orthogonal to each other. The polarization at which the signal is received having the best performance characteristics is determined. Transmissions to the device are routed through appropriate transceivers and antennas such that the signals for the device are transmitted using the same polarization as that of the received signal having the best performance characteristics. Performance characteristics measured may include highest power level, highest signal to noise ratio (SNR), highest carrier to interference ratio (CIR), highest signal to noise plus interference ratio (SNIR), lowest bit error ratio (BER), or lowest block error ratio (BLER).

### BRIEF DESCRIPTION OF THE DRAWINGS

The present invention is further described in the detailed description which follows in reference to the noted plurality of drawings by way of non-limiting examples of embodiments of the present invention in which like reference numerals represent similar parts throughout the several views of the drawings and wherein:

FIG. 1 is a block diagram of a base station according to an example embodiment of the present invention;

FIG. 2 is a flowchart showing a process for transmission polarization selection according to an example embodiment of the present invention;

FIG. 3 is a block diagram of a cellular system according to an example embodiment of the present invention;

FIG. 4 is a flowchart of a process for transmission polarization selection in a system according to an example embodiment of the present invention;

FIG. 5 is a block diagram of a base station for polarization matching according to an example embodiment of the present invention;

FIG. 6 is a block diagram of a base station for polarization selection using multiple transmission antennas and two orthogonal polarizations according to an example embodiment of the present invention;

FIG. 7 is a diagram of transmission antenna using phase hopping according to an example embodiment of the present invention; and

FIG. 8 is a diagram of transmission antenna using delay diversity according to an example embodiment of the present invention.

### DETAILED DESCRIPTION

The particulars shown herein are by way of example and for purposes of illustrative discussion of the embodiments of the present invention. The description taken with the drawings make it apparent to those skilled in the art how the present invention may be embodied in practice.

Further, arrangements may be shown in block diagram form in order to avoid obscuring the invention, and also in view of the fact that specifics with respect to implementation of such block diagram arrangements is highly dependent upon the platform within which the present invention is to be implemented, i.e., specifics should be well within purview of one skilled in the art. Where specific details (e.g., circuits, flowcharts) are set forth in order to describe example embodiments of the invention, it should be apparent to one skilled in the art that the invention can be practiced without these specific details. Finally, it should be apparent that any combination of hard-wired circuitry and software instructions can be used to implement embodiments of the present invention, i.e., the present invention is not limited to any specific combination of hardware circuitry and software instructions.

Although example embodiments of the present invention may be described using an example system block diagram in an example host unit environment, practice of the invention is not limited thereto, i.e., the invention may be able to be practiced with other types of systems, and in other types of environments.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

The present invention relates to method and apparatus for transmission polarization selection where a signal from a device may be received at antenna ports having two or three orthogonal polarizations to each other. It is determined at which polarization the signal is received having the best performance characteristics. Once this is determined, any signals transmitted to the device are transmitted using the same polarization as that of the received signal having the best performance characteristics. The present invention allows the capacity of a base station network to be increased by reducing the average base station transmission power required to serve a given mobile station without requiring a calibration system. Further, the present invention may be implemented in current standard base stations capable of transmit diversity with a simple software upgrade and requires no additional hardware to the base station.

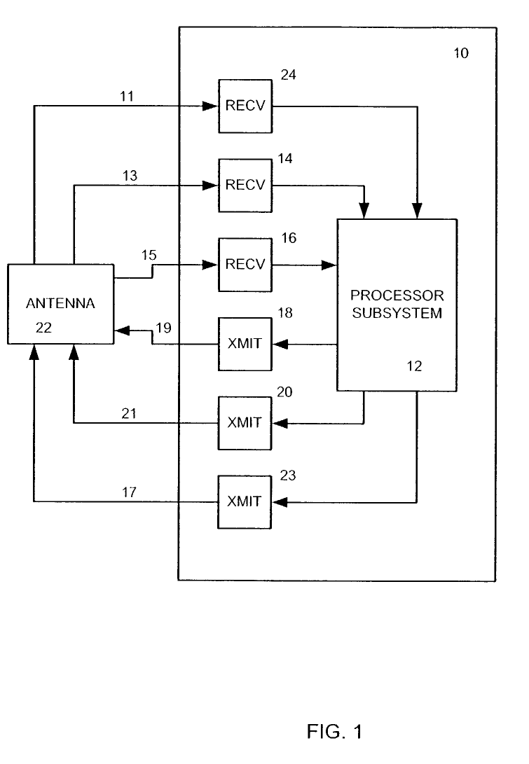

FIG. 1 shows a block diagram of a base station according to an example embodiment of the present invention. A base station 10 may include a processor subsystem 12 along with receivers 24, 14, 16 and antenna receive ports 11, 13 and 15 that receive an incoming signal from a device via one or more antenna 22. Antenna receive ports 11, 13 and 15 have polarizations that are orthogonal to each other. Processor subsystem 12 has circuitry for measuring the performance characteristics of each of the signals received via each of the antenna receive ports 11, 13, 15. The processor subsystem 12 determines which input port (i.e., polarization) is receiving the signal with the best performance characteristics. This determination may be based on any of many criteria all of which are within the limitations of the present invention. The determination of which polarization is receiving the signal with the best performance characteristics may be based on the performance characteristic with the highest value or the performance characteristic with the lowest value. Moreover, the determination which antenna port receives the signal having the best performance characteristics may be made using appropriate time averaging, or may be based on a statistical aspect of the performance characteristic.

Base station 10 may also include transmitters 18, 20, 23 and antenna transmit ports 17, 19, 21 each having a polarization orthogonal to each other. Processor subsystem 12 may transmit signals to the device using one of the antenna transmit ports 17, 19, 21 that has the same polarization as that of the antenna input port 11, 13 or 15 that received the input signal with the best performance characteristics. Therefore, base station 10 may use a different transmitter 18, 20, 23 and antenna transmit port 17, 19 or 21 to transmit a second signal (e.g., on another carrier) to a second device using a different polarization, orthogonal to that of the polarization of the first antenna transmit port. Similar, base station may transmit to a third device using yet a different polarization, orthogonal to the other polarizations. Therefore, according to the present invention, the base station hardware resources are utilized better than in a polarization matching system where the transmitters 18, 20 and 23 would all be needed simultaneously to transmit a signal to a single device. Performance is enhanced by selecting the polarization used to transmit to the device with the polarization that had the best performance characteristics for the received input signal from the device. On average, such selection utilizes that transmission polarization that has the lowest path loss. Base station 10 may be any type of base station in any type of network and/or system and still be within the limitations of the present invention. For example, base station 10 may be a GSM base station, a GSM EDGE base station, a Wireless Local Area Network (WLAN) base station, a TDMA base station, etc.

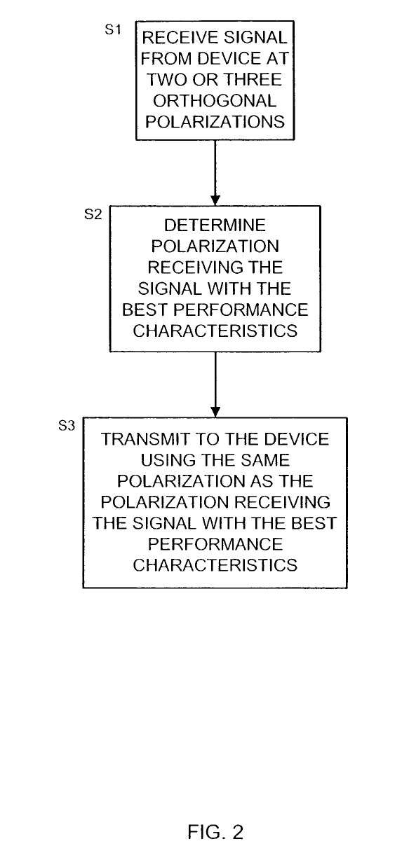

FIG. 2 is a flowchart showing a process for transmission polarization selection according to an example embodiment of the present invention. A signal from a device may be received at two or three orthogonal polarizations S1. It may be determined which polarization is receiving the signal with the best performance characteristics S2. Once this is determined, any transmissions to the device may use the polarization of the received signal with the best performance characteristics S3.

The performance characteristics measured may be any performance type characteristics. For example, the performance characteristic may be the power level received of the signal measured for the two or three orthogonal polarizations. Therefore, the power level for each polarization receive signal may be measured and compared and the signal with the highest power level determined to be the best performance characteristics. To determine the signal with the highest power, appropriate averaging time may be used (e.g., power in a given cell of a single or multiple time slot). Similarly, the signal to noise ratio (SNR) may be used as the performance characteristic measured to determine the best signal. Also, the signal with the maximum or highest carrier to interference ratio (CIR) may be used as the performance characteristic measured. The base station may receive the input signal from the different orthogonal polarizations and combine them. In the combining process of the received signals, the values of the CIR may be already calculated. In this case, there is no need for separate performance measurement calculations and the already calculated measures just have to be sent to the polarization selection control unit. In using the CIR as the performance characteristic, the polarization showing less disturbance (interference of other users) may be used. Therefore, polarization selection based on the CIR automatically takes the load situation in other cells on orthogonal polarizations into account.

Moreover, the signal to noise plus interference ratio (SNIR) may be used as the performance characteristic measure. Also, the bit error ratio (BER) may be used as the performance characteristic measured. BER is also a measure for the combination of connection quality and interference. If soft decision combining is used to combine the received input signals of all polarizations, then a separate performance measuring process may not be needed when using BER as the performance characteristic measure.

Further, block error ratio (BLER) may be used as the performance characteristic measured. This is also a characteristic for the combination of connection quality and interference. The BLER for each polarization may be calculated where the BLER may automatically take the interference situation and the network load on each of the polarizations into account in the polarization selection process. Further, appropriate time averaging or any other appropriate statistical means may be used in the measurement of the chosen performance characteristic.

These are some examples of performance characteristics that may be measured, but the present invention is not limited by these performance characteristics and any other performance characteristics or non-performance characteristics may be used and measured to select an appropriate polarization for transmitting signals to a device and still be within the spirit and scope of the present invention.

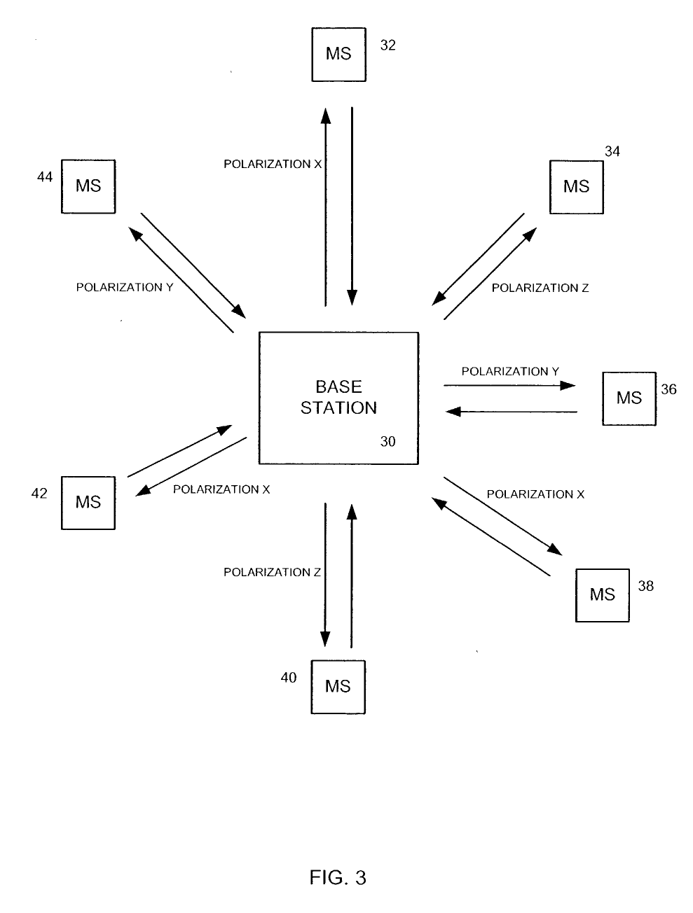

FIG. 3 shows a block diagram of a cellular system according to an example embodiment of the present invention. A base station 30 may simultaneously receive and transmit signals to a plurality of mobile stations (MS) 32-44 using, for example, different carrier frequencies. Each mobile station 32-44 sends a signal to base station 30. Base station 30 receives each input signal from each of mobile stations 32-44 through two or three antenna input ports having orthogonal polarizations. Base station 30 measures the performance characteristics of a signal received from a specific mobile station on each of the polarizations and determines at which polarization the signal with the best performance characteristics is received. The base station 30 then may use the polarization where the signal with the best performance characteristics is received to transmit to that specific mobile station. This may occur for each and every mobile station that the base station is currently servicing.

In this example embodiment, base station 30 has determined that the signal received from mobile station 32 is received on polarization of X with best performance. Therefore, base station 30 transmits signals to mobile station 32 using a polarization of X. Similarly, base station 30 has determined that the signal received from mobile station 34 with the best performance characteristics was received at polarization Z and, therefore, transmits signals to mobile station 34 using a transmit polarization Z. In principle, this allows base station 30 to transmit signals to mobile station 32 and mobile station 34 simultaneously (if desired) using different polarizations and same carrier (e.g., polarization X for mobile station 32 and polarization Z for mobile station 34). However, such usage of this invention may require exceptional channel conditions.

Further, as can be seen in FIG. 3, base station 30 uses transmit polarization Y to transmit to mobile station 36, transmit polarization X to transmit signals to mobile station 38, transmit polarization Z to transmit signals to mobile station 40, transmit polarization X to transmit signals to mobile station 42, and transmit polarization Y to transmit signals to mobile station 44. Polarizations X, Y, Z are orthogonal to each other.

Base station 30 may have separate receive antennas for each orthogonal polarization or multi-polarization antennas having antenna ports for several orthogonal polarizations. Further, base station 30 may have transmit antennas being capable of transmitting on orthogonal polarizations. Further, the orthogonal polarizations may not need to be linear, but any elliptic polarizations. Further, two or three orthogonal polarizations may be implemented in an antenna transmit section of a base station and still be within the limitations and scope of the present invention.

The present invention may be implemented in any of many possible ways. In one example implementation embodiment using just two orthogonal polarizations, a ratio (Rx) of the performance characteristics from the signal received at polarization X (Px) over the performance characteristics of the signal received at polarization Y (Py) may be calculated for the signals from each mobile station in a given cell and time slot (using appropriate averaging as stated previously). Assuming that the base station has N transceivers, half of which may have their transmission ports connected to polarization X (group X) and half to polarization Y (group Y), all mobile stations with Px/Py>1 may have their transmitted signal routed to transceivers of group X. Similarly, mobile stations with Px/Py<1 may be routed to group Y. If there are more than N/2 mobile stations with Px/Py>1, those N/2 users with the largest values of Px/Py may be routed to group X, and the remainder to group Y, regardless of whether their Px/Py is larger than or less than unity. This routing operation may occur for each frame (e.g., Time Division Multiple Access (TDMA) frame), or significantly less frequently. Routing of the signals for transmission to the correct transceivers may not be enough for proper operation. The frequencies of the transceivers may need to be set correctly for all mobile stations at once in each re-routing cycle. With frequency hopping, the transceiver frequencies may need to be set for each slot. In a similar embodiment of the present invention, all mobile stations with Px/Py<1 may have their transmitted signal routed to transceivers of group X, and mobile stations with Px/Py>1 may be routed to group Y.

In another example embodiment of the present invention using just two orthogonal polarizations, the ratios may be calculated and then all ratios sorted by their resultant values. The ratios may be sorted from largest value to smallest value or from smallest value to largest value depending on the type of performance characteristic or the implementation of the present invention. Then, the mobile stations with ratios in one half of the sorted list may be sent signals with a polarization of X, and the mobile stations with values in the other half of the list sent signals using a polarization of Y. Other implementations may be used and still be within the spirit and scope of the present invention.

In still another example implementation embodiment using three orthogonal polarizations, the users are allocated to the group corresponding to that polarization which shows best performance for the user (e.g. user is allocated to group polarization X if P(X)>P(Y) and P(X)>P(Z)).

Moreover, in another example embodiment of the present invention, the users are first again grouped into three groups corresponding to their dominant polarization (as described the previous example implementation). If the number of users inside one group exceeds the number of available resources of that polarization (N/3 in case of three polarizations) then we sort the users inside those groups according to the relation:

$$\frac{P ( polarization having best performance )}{P ( polarization having {2}^{nd} best performance )}$$

in descending order. Those N/3 users having the largest relation are transmitted through that polarization (corresponds to taking just the first N/3 in the list). The others are thrown out of that group and have to be assigned to another group (meaning polarization).

After this process there are three possible states: State 1: It was not necessary to throw any users out of the groups because the resources are sufficient, therefore, the selection is done; State 2: two of three polarizations are fully loaded, thus, those users that were too much are automatically allocated to the single not fully loaded polarization; and State 3: one polarization may have been overloaded, therefore, those users which were too much have to be assigned to the remaining two free polarizations

The grouping in the case of State 3 still must be done (two not fully loaded orthogonal polarizations). The users that have been thrown out of their group may be assigned to one of the other two remaining groups. Thus, they may be assigned to the polarization showing the second best performance.

Specifically, assuming that polarization X is fully loaded and in the groups for polarization Y and polarization Z it is still possible to put some users in. The ratio P(Y)/P(Z) may be calculated for the remaining users and the users sorted in descending order. The group of polarization Y may be filled with the first users in the list having the ratio P(Y)/P(Z) larger than one and the group of polarization Y with the last users in the list having the ratio P(Y)/P(Z) smaller than one. After this, there are again two possible states: State 1: all users are now assigned to one of these polarization groups, thus, the selection is done; and State 2: some users may not even be grouped to the second best polarization, therefore, they may have to be assigned to the remaining polarization being not fully loaded. Thus, the remaining users may be assigned to the single remaining not fully filled polarization.

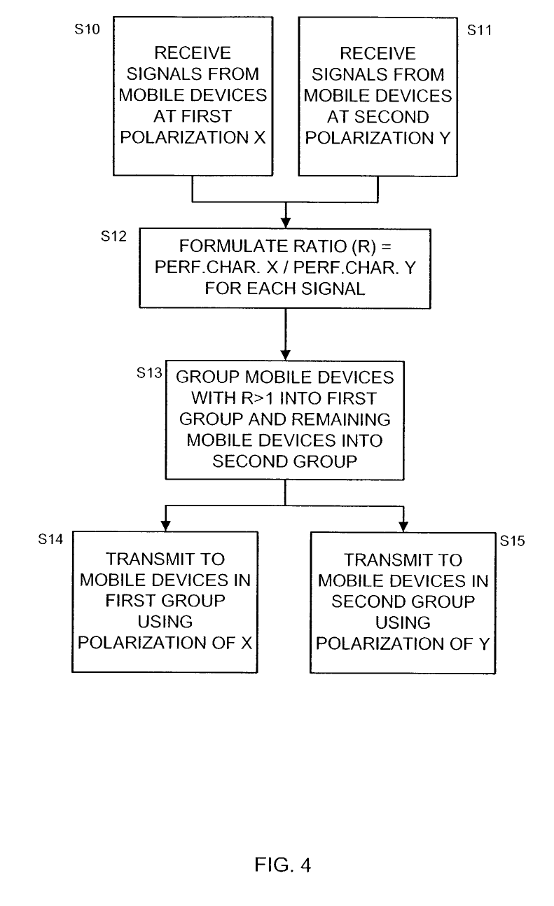

FIG. 4 shows a flowchart of a process for transmission polarization selection in a system according to an example embodiment of the present invention using two orthogonal polarizations. Signals from all mobile devices may be received at a first polarization (X) S10 and at a second polarization(Y) S11. A ratio (R) equal to the performance characteristics of the receive signals from polarization X over the performance characteristics of the receive signals from polarization Y may be calculated for the signal from each mobile device S12. The mobile devices may be grouped where the mobile devices with a ratio R larger than 1 are grouped into a first group and the remaining mobile devices grouped into a second group S13. In another embodiment of the present invention, the mobile devices may be grouped where the mobile devices with a ratio R less than 1 are grouped into a first group and the remaining mobile devices grouped into a second group. The base station may then route transmissions to mobile devices in the first group using a polarization of X S14, and route transmissions to the remaining mobile devices in the second group using a polarization Y S15. The polarization X is orthogonal to the polarization Y.

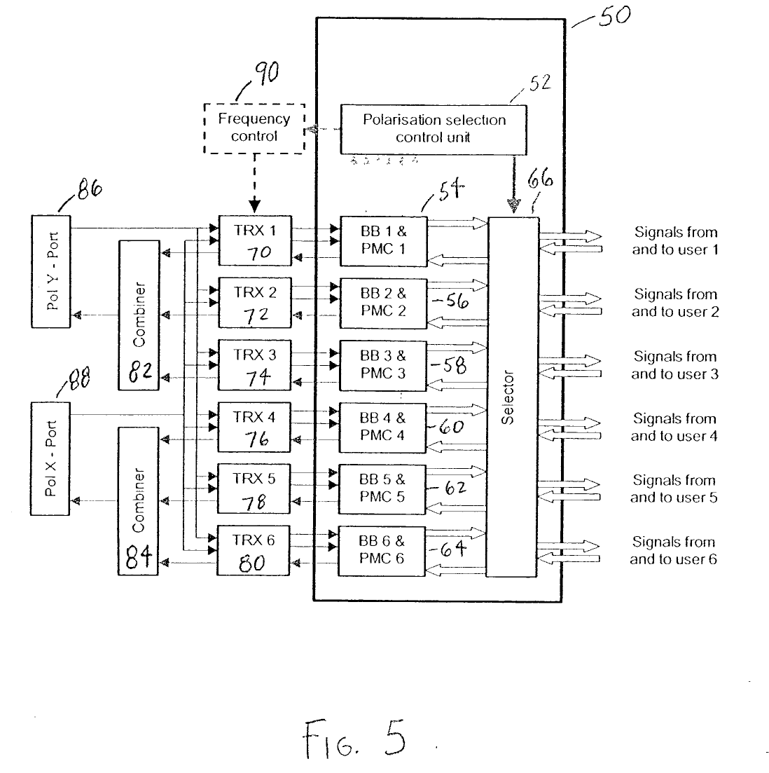

FIG. 5 shows a block diagram of a base station for polarization selection using a single transmission antenna per polarization and two orthogonal polarizations according to an example embodiment of the present invention. The base station includes a processor subsystem 50 that may include a polarization selection control unit 52, selector (e.g., switch, routing matrix) 66, and processors 54-64 that may perform base band processing and performance measurement calculations. The base station may also include one or more transceivers 70-80 whose frequency may be controlled by a frequency controller 90. Controller 90 may be used to change or adjust the frequency for each of the transceivers 70-80. In this example embodiment, one set of transceivers 70-74 may be connected to a combiner 82 that feeds an antenna port 86. The antenna port 86 has a polarization Y. Similarly, a second set of transceivers 76-80 may be connected to a combiner 84 that feeds a second antenna port 88 with a polarization of X, orthogonal to polarization Y.

The processors 54-64 may receive the two received signal streams (on polarization X and polarization Y), combine them, and perform decoding and detection of data. The processors 54-64 may also perform coding and modulation of the digital mobile station data that is to be transmitted to a mobile station. Processors 54-64 may also perform the performance characteristics measurements from the received input data streams, calculate performance ratios and send information regarding this to the polarization selection control unit 52. Polarization selection control unit 52 may use this information to control selector 66 to route transmissions to a particular mobile station to the appropriate transceiver and consequently to the appropriate transmission antenna port with the appropriate polarization.

Control unit 52 may also perform the ratio calculations, sorting, and/or grouping noted previously. Control unit 52 may also control frequency controller 90 which in turn controls the frequency of each of the transceivers 70-80, if additionally frequency hopping based on radio frequency hopping is implemented. In this example embodiment of the present invention, the frequencies of the transceivers may need to be set correctly for each mobile station at least once in each rerouting cycle. In implementing frequency hopping, the transceiver frequencies may need to be set for each slot.

The present invention may transmit using different polarizations in any of many types of transmission schemes, e.g., transmission diversity, antenna array operation, etc. In these schemes, more than just a single antenna may be used for transmission, i.e., several antennas may be used at the same time. Several antenna elements may be also used for reception. The number of antenna elements (i.e., ports) may be a multiple of the number of different polarizations.

According to the present invention, a comparison may be made between the signal quality of the M antennas of polarization X with the signal quality of the M antennas having polarization Y. The transmission polarization may then be selected according to the quality criterion (largest power, SNIR, etc.) discussed previously, and transmit on this polarization using the M antennas having the preferred polarization.

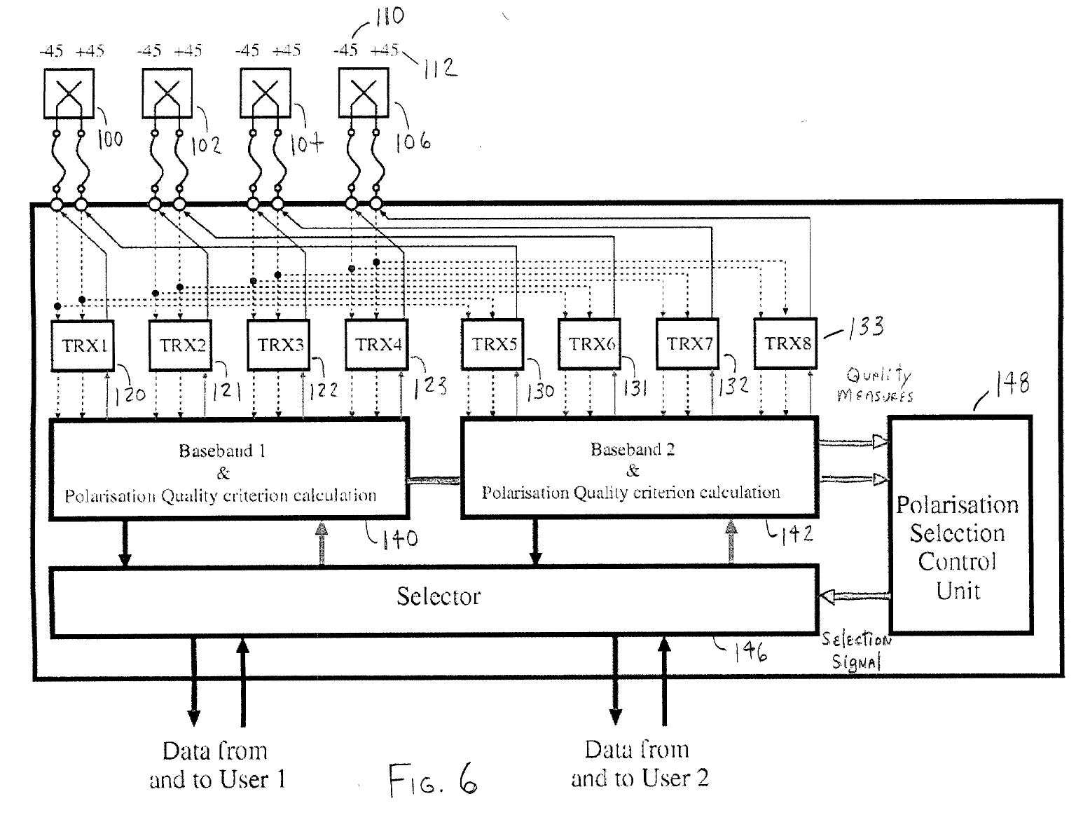

FIG. 6 shows a block diagram of a base station for polarization selection using multiple transmission antennas and two orthogonal polarizations according to an example embodiment of the present invention. In this embodiment, a single user (mobile station) may be served by several antennas 100-106 (in this example, M=4) each having two (or three) orthogonal polarizations 110, 112. Therefore, four actual base station transceivers (TRX) 120-123, 130-133 may be required per user. The signals may be received from a single user from M=4 antennas having polarization X and M=4 antennas having polarization Y (can be either four dual-polarized antennas as illustrated or four single polarized antennas having polarization X and four having polarization Y). The baseband unit 140, 142 considers and combines all the signals to decode the data of each user. The baseband unit 140, 142 has the same tasks as in case of a single dual-polarized antenna (e.g., FIG. 5) but just uses more input signals. During the reception processing of the signals and the detection of the data, the baseband unit 140, 142 derives the performance measure for polarization X and polarization Y. In these performance measurements the signals from all four antenna 100-106 are considered.

The polarization selection may then be performed using selector 146 and control unit 148 as described previously regarding FIG. 5. Depending on the actual polarization situation, either user 1 is transmitted on polarization X and user 2 on polarization Y, or vice versa. If there are more users to serve, then additional signals may need to be combined as illustrated in FIG. 5. Only two users are shown here for illustration. If frequency hopping is applied (as discussed previously), then a frequency control unit similar to that in FIG. 5 may be included that additionally adjusts the frequency of the transceivers 120-123, 130-133.

The present invention may also be implemented using transmission diversity. The basis for transmit (TX) diversity is that data from at least two antennas are transmitted to a single user. In case of polarization selection the better polarization is selected and transmitted over several antennas having the selected polarization. However, the signal that is transmitted from these multiple antennas is not the same. There are several possibilities how the signals on these antennas differ from each other. Some example possibilities include phase hopping, delay diversity, and space-time codes.

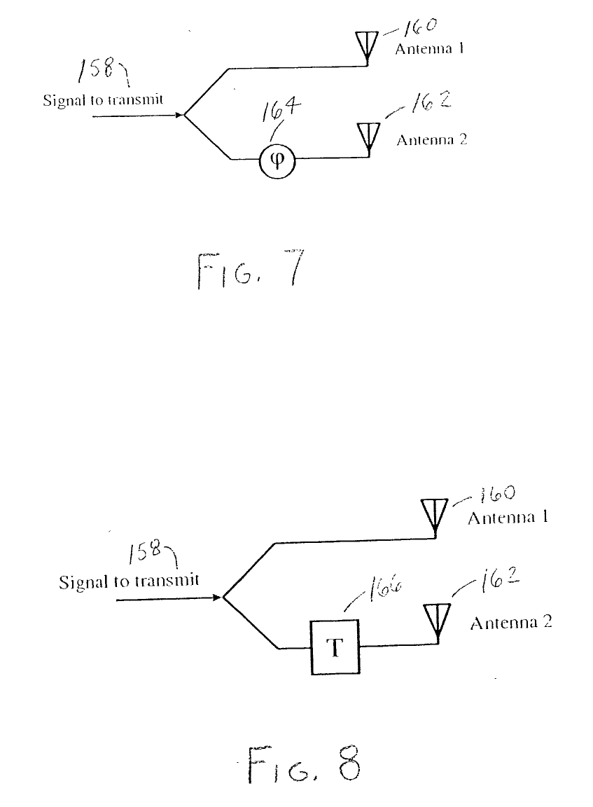

FIG. 7 shows a diagram of transmission antenna using phase hopping according to an example embodiment of the present invention. In phase hopping, a certain phase shift is applied to each antenna where the phase shift is different for each of the antennas. This phase shift may be changed regularly (i.e., “the phase is hopping”). A signal 158 may be transmitted over two (or more) antenna 160, 162, having the same polarization, where before being transmitted over one of the antenna (in this case the second antenna 162) a phase shift is applied.

FIG. 8 shows a diagram of transmission antenna using delay diversity according to an example embodiment of the present invention. In delay diversity, the signals that are transmitted from the different antenna elements are delayed versions of each other. Therefore, instead of a phase shift, the signal 158 undergoes a delay 166 before being transmitted on one of the antenna.

Moreover, space-time codes may be used during implementation of the present invention, where different data streams are created out of the signal to transmit to the user.

Multiple antennas using adaptive array schemes may also be used to implement the present invention. In these schemes, an antenna array may consist of several antenna elements. There are different ways to operate an adaptive array, either TX diversity (discussed previously) or beamforming. In beamforming, the spatial characteristics of the mobile radio channel are used to adapt the transmission beam pattern (the beam direction) of an antenna array (group).

Therefore, according to the present invention, the use of the polarization selection is not restricted to a single antenna per polarization. The present invention may be implemented not only for a single antenna but also for many antennas. Transmission diversity may be used applying, e.g., phase hopping, delay diversity or space-time coding on two or more spatial separated antennas having the selected polarization. Moreover, beamforming or any other kind of adaptive antenna array processing structure/algorithm may be combined with transmission polarization selection according to the present invention.

The present invention is advantageous in that better signal quality or lower transmission power is achieved by selecting the polarization used to transmit to each specific mobile station to match better with the polarization received from that particular mobile station. Further, the present invention is easily implemented by a software upgrade to existing base stations and requires no extra or additional hardware or other functionality such as calibration systems, etc., that add more complexity and additional space in the base station. Moreover, the present invention is advantageous in that even better results may be achieved by combining methods and apparatus according to the present invention with other diversity methods such as frequency hopping, transmission diversity, etc.

It is noted that the foregoing examples have been provided merely for the purpose of explanation and are in no way to be construed as limiting of the present invention. While the present invention has been described with reference to a preferred embodiment, it is understood that the words that have been used herein are words of description and illustration, rather than words of limitation. Changes may be made within the purview of the appended claims, as presently stated and as amended, without departing from the scope and spirit of the present invention in its aspects. Although the present invention has been described herein with reference to particular methods, materials, and embodiments, the present invention is not intended to be limited to the particulars disclosed herein, rather, the present invention extends to all functionally equivalent structures, methods and uses, such as are within the scope of the appended claims.

What is claimed is:

1. A method for transmission polarization selection comprising:
receiving a signal from a device, the signal being received at two or three polarizations, each polarization being orthogonal to each other;
determining the polarization receiving the signal having the best performance characteristics; and
transmitting to the device using a polarization the same as that receiving the signal having the best performance characteristics.

2. The method according to claim 1, further comprising determining the polarization receiving the signal having the highest power level and transmitting to the device using a polarization the same as that receiving the signal having the highest power level.

3. The method according to claim 1, further comprising determining the polarization receiving the signal having the highest signal-to-noise ratio (SNR) and transmitting to the device using a polarization the same as that receiving the signal having the highest SNR.

4. The method according to claim 1, further comprising determining the polarization receiving the signal having the highest carrier-to-interference ratio (CIR) and transmitting to the device using a polarization the same as that receiving the signal having the highest CIR.

5. The method according to claim 1, further comprising determining the polarization receiving the signal having the highest signal-to-noise plus interference ratio (SNIR) and transmitting to the device using a polarization the same as that receiving the signal having the highest SNIR.

6. The method according to claim 1, further comprising determining the polarization receiving the signal having the lowest bit error ratio (BER) and transmitting to the device using a polarization the same as that receiving the signal having the lowest BER.

7. The method according to claim 1, further comprising determining the polarization receiving the signal having the lowest block error ratio (BLER) and transmitting to the device using a polarization the same as that receiving the signal having the lowest BLER.

8. The method according to claim 1, further comprising determining the polarization receiving the signal having the best performance characteristics using appropriate time averaging.

9. The method according to claim 1, further comprising determining the polarization receiving the signal having the best performance characteristics based on a statistical aspect of the performance characteristic.

10. The method according to claim 1, further comprising receiving a signal from a device, the signal being received at a single antenna having antenna ports having orthogonal polarizations to each other.

11. The method according to claim 1, further comprising receiving a signal from a device, the signal being received at two or three antennas each having orthogonal polarizations to each other.

12. The method according to claim 1, further comprising receiving a signal from a device, the signal being received at two or more antennas per orthogonal polarization.

13. The method according to claim 12, further comprising transmitting to the device using transmission diversity techniques.

14. The method according to claim 13, further comprising transmitting to the device using at least one of phase hopping, delay diversity, and space-time codes.

15. The method according to claim 12, further comprising transmitting to the device using beamforming.

16. A method for transmission polarization selection at a base station comprising:
receiving a signal from each of a plurality of mobile devices, each signal being received at a base station, each signal being received at polarizations orthogonal to each other;
determining for each signal received from each mobile device the polarization receiving the signal having the best performance characteristics; and
transmitting to each mobile device using a polarization the same as that receiving the signal having the best performance characteristics for the received signal from that mobile device.

17. The method according to claim 16, further comprising determining for each signal received from each mobile device the polarization receiving the signal having the highest power level and transmitting to each mobile device using a polarization the same as that receiving the signal having the highest power level for the received signal from that mobile device.

18. The method according to claim 16, further comprising determining for each signal received from each mobile device the polarization receiving the signal having the highest signal-to-noise ratio (SNR) and transmitting to each mobile device using a polarization the same as that receiving the signal having the highest SNR for the received signal from that mobile device.

19. The method according to claim 16, further comprising determining for each signal received from each mobile device the polarization receiving the signal having the highest carrier-to-interference ratio (CIR) and transmitting to each mobile device using a polarization the same as that receiving the signal having the highest CIR for the received signal from that mobile device.

20. The method according to claim 16, further comprising determining for each signal received from each mobile device the polarization receiving the signal having the highest signal-to-noise plus interference ratio (SNIR) and transmitting to each mobile device using a polarization the same as that receiving the signal having the highest SNIR for the received signal from that mobile device.

21. The method according to claim 16, further comprising determining for each signal received from each mobile device the polarization receiving the signal having the lowest bit error ratio (BER) and transmitting to each mobile device using a polarization the same as that receiving the signal having the lowest BER for the received signal from that mobile device.

22. The method according to claim 16, further comprising determining for each signal received from each mobile device the polarization receiving the signal having the lowest block error ratio (BLER) and transmitting to each mobile device using a polarization the same as that receiving the signal having the lowest BLER for the received signal from that mobile device.

23. The method according to claim 16, further comprising:
formulating a ratio, for the signal received from each mobile device, comprising the performance characteristics of the signal received at one polarization as a numerator and the performance characteristics of the signal received at another polarization as the denominator;
calculating values of the ratios and sorting these values into a list from highest value to lowest value;
transmitting to the mobile devices with ratio values in the upper half of the list using a polarization the same as that which received the signals with performance characteristics in the numerator of the ratios; and
transmitting to the mobile devices with ratio values in the lower half of the list using a polarization the same as that which received the signals with performance characteristics in the denominator of the ratios.

24. The method according to claim 16, further comprising:
formulating a ratio, for the signal received from each mobile device, comprising the performance characteristics of the signal received at one polarization as a numerator and the performance characteristics of the signal received at another polarization as the denominator;
calculating values of the ratios and sorting these values into a list from lowest value to highest value;
transmitting to the mobile devices with ratio values in the upper half of the list using a polarization the same as that which received the signals with performance characteristics in the numerator of the ratios; and
transmitting to the mobile devices with ratio values in the lower half of the list using a polarization the same as that which received the signals with performance characteristics in the denominator of the ratios.

25. The method according to claim 16, further comprising:
formulating a ratio, for the signal received from each mobile device, comprising the performance characteristics of the signal received at one polarization as a numerator and the performance characteristics of the signal received at another polarization as the denominator;
calculating values of the ratios and grouping the values larger than one into a first group and the remainder of the values into a second group;
transmitting to the mobile devices with ratio values in the first group using a polarization the same as that which received the signals with performance characteristics in the numerator of the ratios; and
transmitting to the mobile devices with ratio values in the second group using a polarization the same as that which received the signals with performance characteristics in the denominator of the ratios.

26. The method according to claim 16, further comprising:
formulating a ratio, for the signal received from each mobile device, comprising the performance characteristics of the signal received at one polarization as a numerator and the performance characteristics of the signal received at another polarization as the denominator;
calculating values of the ratios and grouping the values less than one into a first group and the remainder of the values into a second group;
transmitting to the mobile devices with ratio values in the first group using a polarization the same as that which received the signals with performance characteristics in the numerator of the ratios; and
transmitting to the mobile devices with ratio values in the second group using a polarization the same as that which received the signals with performance characteristics in the denominator of the ratios.

27. The method according to claim 16, further comprising transmitting to each mobile device using two or more antennas having the same polarization.

28. The method according to claim 27, further comprising transmitting to each mobile device using transmission diversity techniques.

29. The method according to claim 28, further comprising transmitting to each mobile device using at least one of phase hopping, delay diversity, and space-time codes.

30. The method according to claim 27, further comprising transmitting to each mobile device using beamforming.

31. A base station for transmission polarization selection comprising:
at least two antenna receive ports, the at least two antenna receive ports having at least two orthogonal polarizations, the at least two antenna receive ports receiving a signal from a mobile device;
at least two antenna transmit ports, the at least two antenna transmit ports having at least two orthogonal polarizations; and
a processor subsystem, the processor subsystem measuring performance characteristics of the signal received at each at least two antenna receive ports, the processor subsystem determining which antenna receive port received the signal with the best performance characteristics and controlling transmissions from the base station to the mobile device to be sent on the at least two antenna transmit ports having the same polarization as the antenna receive port receiving the signal with the best performance characteristics.

32. The base station according to claim 31, further comprising at least two transceivers operatively connected to the at least two antenna receive ports and the at least two antenna transmit ports.

33. The base station according to claim 32, the processor subsystem further comprising a frequency controller, the frequency controller capable of adjusting a radio frequency of each at least two transceivers.

34. The base station according to claim 32, the processor subsystem further comprising at least one base band processor, one base band processor being associated with each at least two transceivers and performing base band processing for signals received and transmitted between the base station and the mobile device.

35. The base station according to claim 32, the processor subsystem further comprising a selection unit, the selection unit routing signals for transmission to the mobile device to the appropriate at least one transceiver.

36. The base station according to claim 35, the processor subsystem further comprising a control unit, the control unit receiving information regarding which antenna receive port(s) having a single polarization received the signal with the best performance characteristics and controlling the selection unit to route the signals for transmission to the mobile device to the appropriate at least one transceiver.

37. The base station according to claim 32, further comprising at least two combiner units, each combiner unit routing signals received from a subset of the at least two transceivers to one antenna transmit port with a given polarization.

38. The base station according to claim 31, the processor subsystem further comprising a performance measuring unit for measuring the power level of the signal received at the at least one antenna receive port of each polarization.

39. The base station according to claim 31, the processor subsystem further comprising a performance measuring unit for measuring the signal-to-noise ratio (SNR) of the signal received at the at least one antenna receive port of each polarization.

40. The base station according to claim 31, the processor subsystem further comprising a performance measuring unit for measuring the carrier-to-interference ratio (CIR) of the signal received at the at least one antenna receive port of each polarization.

41. The base station according to claim 31, the processor subsystem further comprising a performance measuring unit for measuring the signal-to-noise plus interference ratio (SNIR) of the signal received at the at least one antenna receive port of each polarization.

42. The base station according to claim 31, the processor subsystem further comprising a performance measuring unit for measuring the bit error ratio (BER) of the signal received at the at least one antenna receive port of each polarization.

43. The base station according to claim 31, the processor subsystem further comprising a performance measuring unit for measuring the block error ratio (BLER) of the signal received at the at least one antenna receive port of each polarization.

44. The base station according to claim 31, wherein the base station comprises a GSM base station.

45. The base station according to claim 31, wherein the base station comprises a GSM EDGE base station.

46. The base station according to claim 31, wherein the base station comprises a Wireless Local Area Network (WLAN) base station.

47. The base station according to claim 31, wherein the base station comprises a TDMA base station.

48. An apparatus comprising a storage medium with instructions stored therein, the instructions when executed causing a computing device to perform:
receiving a signal from a device, the signal being received at two or three polarizations orthogonal to each other;
determining the polarization receiving the signal having the best performance characteristics; and
transmitting to the device using a polarization the same as that receiving the signal having the best performance characteristics.
